(19) United States
(12) Patent Application Publication
(10) Pub. No.: US 2026/0328860 A1
(43) Pub. Date: Oct. 22, 2026

(54) LOSSY INDUCTOR-BASED DIRECT CURRENT LOAD FOR POWER DELIVERY AND THERMAL VERIFICATION

(71) Applicant: AMD Design, LLC, Wilmington, DE (US)

(72) Inventor: Aurelio Rodriguez ECHEVARRIA, Bellevue, WA (US)

(73) Assignee: AMD Design, LLC, Wilmington, DE (US)

(21) Appl. No.: 19/183,084

(22) Filed: Apr. 18, 2025

(51) Int. Cl. G01R 31/40; G01R 19/15; H02M 1/34; H02M 3/00; H05K 1/02; H05K 1/16

(52) U.S. Cl. CPC G01R 31/40; G01R 19/15; H02M 1/348; H02M 3/003; H05K 1/0201; H05K 1/165; H05K 1/167; H05K 2201/10015

(57) ABSTRACT

Systems and devices for power delivery and thermal verifications are described. A device can include a step-up converter configured to receive a setpoint input that indicates a desired amount of power to draw from a power source, draw direct current (DC) power from the power source according to the setpoint input, and step up a voltage of the DC power to generate an output voltage. The device can further include at least one lossy inductor connected to an input terminal of the step-up converter. The at least one lossy inductor can be configured to convert an input current of the DC power being drawn into a first amount of heat. The device can further include a pulse load connected to an output terminal of the step-up converter. The pulse load can be configured to convert a current of the output voltage into a second amount of heat.

### FIELD

The present disclosure relates in general to controlling slew rates of direct current (DC) power being provided to a load, particularly, DC power from a power shelf to a server.

### BACKGROUND

A data center can house a large number of servers, storage systems, and networking equipment. The data center can provide infrastructure such as power, cooling and security necessary to ensure that the servers operate efficiently and reliably. The servers in the data center can have various types of workloads such as data processing, storage, and networking tasks. To support the servers, the data center needs to provide sufficient infrastructure such as sufficient power, storage, networking equipment, etc. For example, infrastructure provided by cloud-based data centers can be installed with various types of power source such as uninterruptible power supplies (UPS), AC/DC power supply, power shelf, power distribution board (PDB), and any power source or backup power systems that provide power to the data center at different operating conditions.

### SUMMARY

A device is described herein. The device can include a step-up converter configured to receive a setpoint input that indicates a desired amount of power to draw from a power source, draw direct current (DC) power from the power source according to the setpoint input, and step up a voltage of the DC power to generate an output voltage. The device can further include at least one lossy inductor connected to an input terminal of the step-up converter. The at least one lossy inductor can be configured to convert an input current of the DC power being drawn into a first amount of heat. The device can further include a pulse load connected to an output terminal of the step-up converter. The pulse load can be configured to convert a current of the output voltage into a second amount of heat.

A system is also described herein. The system includes at least one monitor device and an electrical load. The electrical load can include a step-up converter configured to receive a setpoint input that indicates a desired amount of power to draw from a power source, draw direct current (DC) power from the power source according to the setpoint input, and step up a voltage of the DC power to generate an output voltage. The device can further include at least one lossy inductor connected to an input terminal of the step-up converter. The at least one lossy inductor can be configured to convert an input current of the DC power being drawn into a first amount of heat. The device can further include a pulse load connected to an output terminal of the step-up converter. The pulse load can be configured to convert a current of the output voltage into a second amount of heat. The at least one monitor device can be configured to verify power delivery of the power source based on the DC power being drawn.

A structure is also described herein. The structure can include a printed circuit board (PCB). The structure can further include a step-up converter constructed on the PCB. The step-up converter can be configured to receive a setpoint input that indicates a desired amount of power to draw from a power source. The step-up converter can be further configured to draw direct current (DC) power from the power source according to the setpoint input. The step-up converter can be further configured to step up a voltage of the DC power to generate an output voltage. The structure can further include at least one lossy inductor constructed on the PCB. The at least one lossy inductor can be connected to an input terminal of the step-up converter. The at least one lossy inductor can be configured to convert an input current of the DC power being drawn into a first amount of heat. The structure can include a pulse load constructed on the PCB. The pulse load can be connected to an output terminal of the step-up converter. The pulse load can be configured to convert a current of the output voltage into a second amount of heat.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates a system that can implement lossy inductor-based direct current load for power delivery and thermal verification in one embodiment.

FIG. 2 illustrates an example implementation of a lossy inductor-based direct current load for power delivery and thermal verification in one embodiment.

FIG. 3 illustrates another example implementation of a lossy inductor-based direct current load for power delivery and thermal verification in one embodiment.

FIG. 4 illustrates an example structure of a lossy inductor-based direct current load for power delivery and thermal verification in one embodiment.

### DETAILED DESCRIPTION

### Overview

Power delivery verification of a power source is a test to verify whether the power source is functioning properly, such as whether the power source is capable of providing power it is meant to provide. Power delivery verification can use loads for simulating operational or real load which the power sources are meant to support. Data centers can include and utilize various types of power sources at different operating conditions. The different types of power sources can include, but not limited to, uninterruptible power supplies (UPS), AC/DC power supply, power shelf, power distribution board (PDB), and any power source or backup power systems that provide power to loads in the data center.

In an aspect, power delivery verification in data centers, at the rack level, can be performed for the different power sources individually, or can be done for arrangements of different combinations of different power sources. To perform power delivery verification for an arrangement of different power sources, the load being used for the simulation is a direct current (DC) load. The DC load can be programmable by users to simulate different levels of power demand. However, despite being programmable, it is difficult to use DC loads to simulate load profiles that are representative of the mix of workloads that users could use in their systems on a single rack. DC loads can also be relatively large physically, which takes up physical space in the data center. For example, to simulate load profiles that have a mixture of loads having relatively high-power demand, additional DC loads are needed but the safe operating area in the data center will be reduced.

In an aspect, additional DC loads are needed for testing higher power demand due to limitations of conventional DC loads to draw higher power. For example, a conventional DC load uses the saturation or linear region of a metal-oxide-semiconductor field-effect transistor (MOSFET) to program a constant current to be drawn by the DC load. A control loop in the DC load can maintain the constant current and apply the proper gate to source voltage (Vgs) to program the MOSFET. However, the MOSFET can heat up and there is a need to spread and dissipate the heat. As the power demand increases, more heat is generated. Hence, to prevent overheating the MOSFET, a single DC load can be limited in the amount of power demand being tested, and testing of higher power demand require addition DC loads.

Further, data centers can include cooling systems for preventing overheating of components and environment in the data center. Thermal verification can also be performed on the cooling systems to ensure that the cooling systems are functioning properly. Thermal verification can include monitoring temperature distribution of components in the cooling system. For example, cold plates are typically attached to heat-generating components and are used for transferring heat to a cooling medium. The cold plate can be verified by testing whether the temperature of the cold plate is maintained within a stable temperature range. However, separate heat-generating loads may need to be attached to the cooling system for the verification, and the heat-generating loads need to be controlled to generate heat for testing the cooling system. Hence, power delivery verification and thermal verification are typically performed separately.

In the present disclosure, a DC load that can be utilized for both power delivery and thermal verification is disclosed and described. The DC load described herein can include a boost or step-up converter, at least one lossy inductor and a pulse load. The step-up converter can include a current loop to draw a programmable constant current from a power source for power delivery verification. The at least one lossy inductor and the pulse load can provide additional heat dissipation for the DC load, such that higher power demand during power delivery verification can be achieved. Further, the step-up converter, the at least one lossy inductor and the pulse load can be built on a metal based printed circuit board (PCB) that can function as a heat spreader and can directly interface with cooling system components, such as a heat sink or a cold plate, to perform thermal verification.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example System

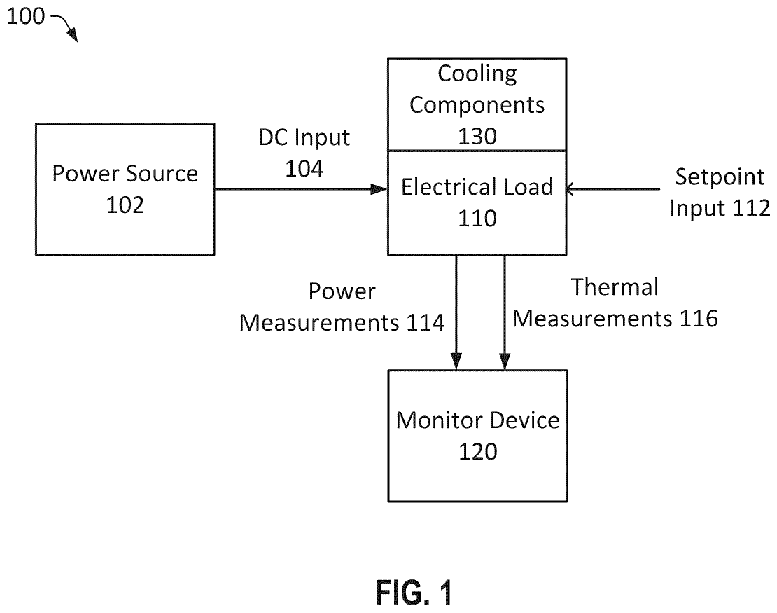

FIG. 1 illustrates a system 100 that can implement lossy inductor-based direct current load for power delivery and thermal verification in one embodiment. In one embodiment, system 100 can be implemented in a server rack in a data center. System 100 can include at least a power source 102, an electrical load 110, at least one monitor device 120 and at least one cooling component 130. Power source 102 can include, for example, one or more of uninterruptible power supplies (UPS), AC/DC power supply, power shelf, power distribution board (PDB), and any power source or backup power systems that provide power to a data center that includes system 100.

Electrical load 110 can be a DC load configured to draw a DC input 104 from power source 102. Electrical load 110 can receive a user input, such as a setpoint input 112, from a user interface including but not limited to, physical mechanisms (e.g., buttons, knobs, switches, or the like), computing device input interface (e.g., computer mouse, keyboard, touchscreen, or the like), or other types of user interface that can provide digital or analog input encoding values, parameters, messages or commands to operate electrical load 110.

In one embodiment, setpoint input 112 can be an input signal encoding a desired amount of power or current to be drawn from power source 102. A controller (described below) within electrical load 110 can be configured to decode setpoint input 112 and, according to the decoded setpoint input 112, control the amount of power or current (e.g., determine DC input 104) to draw from power source 102.

Monitor device 120 can be a monitoring system for measuring electrical parameters, such as voltage and current, from electrical load 110. The measured electrical parameters can be used for determining a result of power delivery verification and/or thermal verification. In some embodiments, monitor device 120 can include probes for measuring electrical parameters and/or thermal information from electrical load 110 and/or cooling components 130.

By way of example, in performing power delivery verification of power source 102, a user can input, by providing setpoint input 112, a desired amount of power to be drawn by electrical load 110 from power source 102. Electrical load 110 can decode setpoint input 112 and draw a specific amount of power, as DC input 104, from power source 102. The specific amount of power being drawn can be provided to monitor device 120 as power measurements 114. Monitor device 120 can compare power measurements 114 with the desired amount of power indicated in setpoint input 112. If a difference between power measurements 114 and the desired amount of power is within a predefined threshold range, such as a predefined tolerance, then monitor device 120 can output an indication that power source 102 is functioning properly and is capable of providing the desired amount of power indicated by setpoint input 112. If the difference is outside of the predefined threshold range, then monitor device 120 can output an indication that power source 102 may not be functioning properly and may be incapable of providing the desired amount of power indicated by setpoint input 112. In one embodiment, monitor device 120 can include memory devices configured to store the predefined threshold range.

In an aspect, when power source 102 is a UPS that may not be in operation continuously and remain unused for a long period of time, power delivery verification of the UPS can ensure that the UPS can function correctly when needed. In another aspect, power delivery verification can also test power source 102 to ensure that power source 102 is capable to providing the maximum expected power according to predefined specifications. Regularly scheduled power delivery verification can ensure that power sources that may be degrading due to age and environmental surroundings are still functioning to provide sufficient power.

Cooling components 130 can include, for example, heat sinks, cold plates, temperature sensors, or other components suitable to be parts of a cooling system of a data center. Various components of electrical load 110 can be built on a metal-core PCB and the metal-core PCB can function as a heat spreader. The PCB can be attached to cooling components 130. Verification of cooling components 130 can be performed simultaneously with power delivery verification of power source 102 by operating electrical load 110. As electrical load 110 draws DC input 104 from power source 102, electrical load 110 can produce heat. To be described in more detail below, electrical load 110 can include internal components for dissipating heat. The dissipated heat can spread to cooling components 130, and temperatures or other thermal information, labeled as thermal measurements 116, can be provided to monitor device 120.

Monitor device 120 can compare thermal measurements 116 with predefined thermal parameters. If a difference between thermal measurements 116 and the predefined thermal parameters is within a predefined temperature range, such as a predefined tolerance, then monitor device 120 can output an indication that cooling components 130 are functioning properly. If a difference between thermal measurements 116 and the predefined thermal parameters is outside of the predefined temperature range, then monitor device 120 can output an indication that cooling components 130 may not be functioning properly. In one embodiment, monitor device 120 can include memory devices configured to store the predefined temperature range. In one embodiment, the stored predefined temperature range can include mappings between temperature ranges and power being drawn. By way of example, the stored predefined temperature range can indicate that if power measurement 114 is X, then thermal measurements 116 shall be within a temperature range Y. If thermal measurements is outside of the temperature range Y, then cooling components 130 may not be functioning properly for the amount of power X being drawn from power source 102.

### First Example Implementation

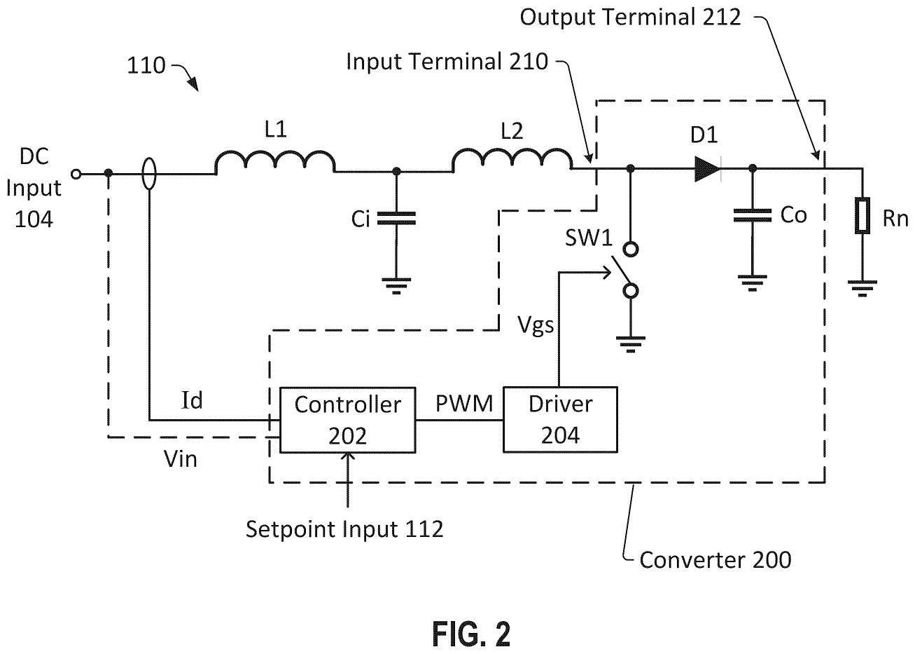

FIG. 2 illustrates an example implementation of a lossy inductor-based direct current load for power delivery and thermal verification in one embodiment. Descriptions of FIG. 2 can reference components that are shown in FIG. 1. In an embodiment shown in FIG. 2, electrical load 110 can include a converter 200, at least one inductor labeled as L1 and L2, an input capacitor Ci, and a pulse load Rn. Converter 200 can include a controller 202, a driver 204, a switching element SW1, a diode D1 and an output capacitor Co. Converter 200 can be a boost converter or step-up converter configured to convert or step up an input voltage (e.g., DC input 104) into a higher voltage.

Controller 202 can be formed by one or more semiconductor devices. Controller 202 can be configured to control or regulate the operations of converter 200. Controller 202 can be an integrated circuit including, for example, a processor, central processing unit (CPU), field-programmable gate array (FPGA), various analog and/or digital logic circuits, or any other circuitry that is configured to operate various aspects of converter 200, such as controlling and operating driver 204 for driving switching element SW1. While described as a CPU in illustrative embodiments, controller 202 is not limited to a CPU in these embodiments and may comprise any other circuitry that is configured to control and operate driver 204.

Controller 202 can be configured to generate control signals, such as pulse width modulation (PWM) signals, and provide the generated control signals to driver 204. Drivers 204 can generate a current for driving switching element SW1 to switch on (e.g., conductive) and switch off (e.g., non-conductive) at a specific switching frequency. In one embodiment, controller 202 can receive setpoint input 112 and generate the PWM signals according to the desired amount of power indicated by setpoint input 112. Further, controller 202 can perform current sensing to monitor input current Id of DC input 104. Controller 202 can include a current loop that setting the switching frequency of switching element SW1 to maintain Id at a constant current according to the desired amount of power indicated by setpoint input 112. In one embodiment, controller 202 can perform voltage sensing to monitor an input voltage Vin of DC input 104. Controller 202 can include a voltage control loop that sets the switching frequency of switching element SW1 to maintain Vin at a constant voltage according to the desired amount of power indicated by setpoint input 112. When both Vin and Id are being sensed, the setpoint input 112 can represent a power input, such as representing a desired power level for controller 202 to operate electric load 110 to dissipate a selected amount of power.

When switching element SW1 is switched off, an input current Id of the DC input 104 can charge input capacitor Ci and lossy inductors L1, L2. When switching element SW1 is switched on, the input capacitor Ci and lossy inductors L1, L2 can be triggered to discharge current to an input terminal 210 of converter 200, and the discharged current can flow to an output terminal 212 of converter 200 via diode D1. The output voltage at the output terminal 212 is greater than the input voltage at input terminal 210, thus stepping up the voltage of DC input 104.

A lossy inductor is an inductor that is intentionally built with a high DC resistance. DC resistance is an inherent resistance of the inductor, such as wire resistance in the case where the inductor is formed by winding of wires. The high DC resistance of a lossy inductor can allow the lossy inductor to function as both an inductor and a heat dissipative element. As current flows through the inductor, losses caused by the high DC resistance can dissipate energy, such as heat. The heat being dissipated by the lossy inductors L1, L2 in electrical load 110 can provide a temperature balance by alleviating the heat being generated at switching element SW1. When switching element SW1 is switched off, lossy inductors L1, L2 can convert the input Id current of DC input 104 into a first amount of heat.

In one embodiment, pulse load Rn can be implemented by a non-inductive load resistor. A non-inductive load resistor can function as a heat dissipative element by converting electrical energy into heat. As current of the output voltage from output terminal 212 flows to Rn, Rn can convert the current into heat. While other types of resistors may have windings or coils that introduce inductance, a non-inductive resistor can be designed to minimize or eliminate inductive effects, such as by having windings arranged to cancel each other's inductance. Due to the lack of inductive effects, the non-inductive resistor does not create inductive reactance, hence functioning as a purely resistive load and provides a stable source of heat dissipation. Further, the design of non-inductive resistors to minimize inductive effects can span relatively larger surface areas such that it can be constructed on a large surface, such as being printed on a PCB. Hence, non-inductive resistors can be constructed on PCBs that can be mounted with cooling components such as heatsinks to improve heat dissipation. When switching element SW1 is switched on, lossy inductors L1, L2 can convert the input Id current of DC input 104 into a first amount of heat and pulse load Rn can convert the current from the output voltage of converter 200 into a second amount of heat. The different amount of heat being generated by lossy inductors L1, L2 and pulse load Rn at different operating conditions, can provide thermal balance across electrical load 110.

### Second Example Implementation

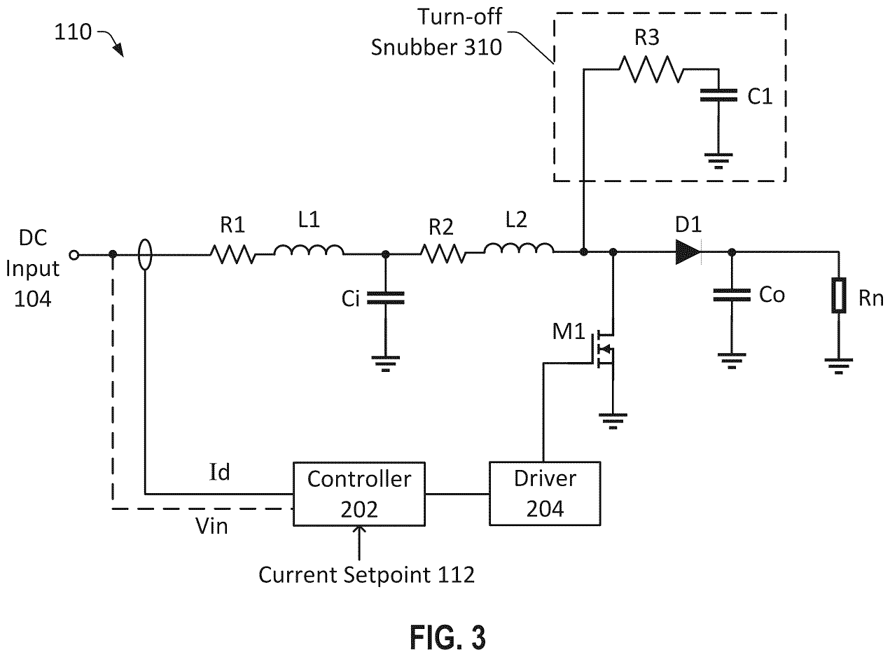

FIG. 3 illustrates another example implementation of a lossy inductor-based direct current load for power delivery and thermal verification in one embodiment. Descriptions of FIG. 3 can reference components that are shown in FIG. 1 and FIG. 2. In an embodiment shown in FIG. 3, switch SW1 can be implemented by a transistor, such as a MOSFET M1, that is a part of converter 200. The lossy inductors L1, L2 can have inherent DC resistance R1, R2, respectively. Further, in the embodiment shown in FIG. 3, electrical load 110 can further include a turn-off snubber 310. Turn-off snubber 310 is a circuit configured to limit the voltage spike across a switching element SW1 (or transistor M1) when switching element SW1 is being switched off. In the embodiment shown in FIG. 3, turn-off snubber 310 can be implemented by a resistor R3 and a capacitor C1 connected in series. In some embodiments, turn-off snubber 310 can be implemented by a resistor and a diode.
When the switching frequency to switch M1 is relatively high, electrical load 110 can function as a multi-kilowatt DC load that can handle relatively high voltages, such as 54 VDC to 400 VDC. Conventional DC load that do not utilize step-up converters with internal heat dissipative elements (e.g., L1, L2, Rn) may be limited to lower voltages due to safe operation area limitations (e.g., less physical space) that limits the number of conventional DC loads that can be used.

### Example Structure

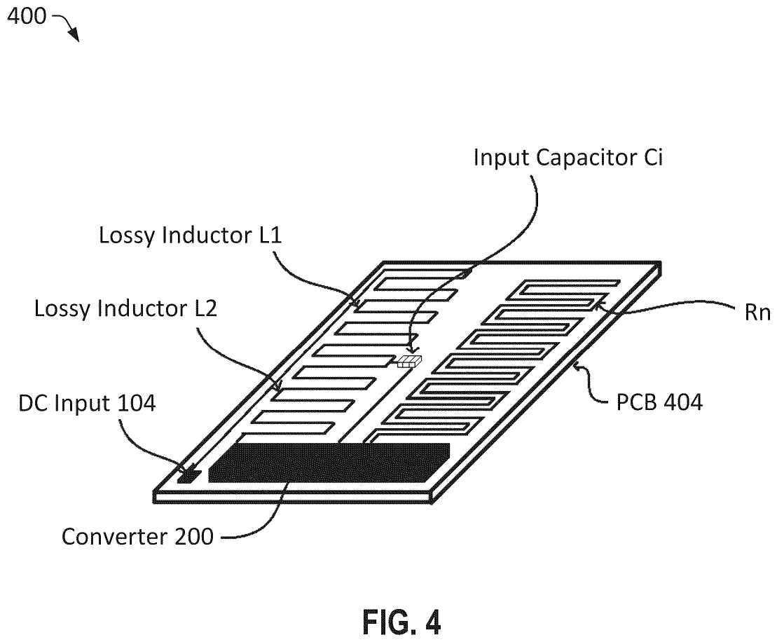

FIG. 4 illustrates an example structure of a lossy inductor-based direct current load for power delivery and thermal verification in one embodiment. Descriptions of FIG. 4 can reference components that are shown in FIG. 1 and FIG. 3. An example structure 400 is shown in FIG. 4. Structure 400 can include a PCB 404 and components of electrical load 110 constructed or built on PCB 404. PCB 404 can be a metal-core PCB, such as an aluminum-based PCB or a copper-based PCB. PCB 404 can function as a heat spreader and can interface (e.g., attach to) with cooling components 130. In one embodiment, lossy inductors L1, L2, and pulse load Rn can be printed on PCB 404 prior to mounting converter 200, input capacitor Ci, and a conductive pad for receiving DC input 104, on PCB 404.

### Examples

Example 1: A device comprising: a step-up converter configured to: receive a setpoint input that indicates a desired amount of power to draw from a power source; draw direct current (DC) power from the power source according to the setpoint input; and step up a voltage of the DC power to generate an output voltage; at least one lossy inductor connected to an input terminal of the step-up converter, wherein the at least one lossy inductor is configured to convert an input current of the DC power being drawn into a first amount of heat; and a pulse load connected to an output terminal of the step-up converter, wherein the pulse load is configured to convert a current of the output voltage into a second amount of heat.
Example 2: The device of Example 1, wherein the at least one lossy inductor includes a first lossy inductor and a second lossy inductor.
Example 3: The device of any one of Examples 1 and 2, wherein the first lossy inductor is connected between the power source and an input capacitor; and the second lossy inductor is connected between the input capacitor and an input terminal of the step-up converter.
Example 4: The device of any one of Examples 1 to 3, wherein the pulse load is a non-inductive load resistor.
Example 5: The device of any one of Examples 1 to 4, further comprising a turn-off snubber connected between the at least one lossy inductor and an output terminal of the step-up converter.
Example 6: The device of any one of Examples 1 to 5, wherein the step-up converter, the at least one lossy inductor and the pulse load are constructed on a printed circuit board (PCB).
Example 7: The device of any one of Examples 1 to 6, wherein the PCB is a metal-core PCB interfaced with at least one cooling component.
Example 8: A system comprising: at least one monitor device; and an electrical load comprising: a step-up converter configured to: receive a setpoint input that indicates a desired amount of power to draw from a power source; draw direct current (DC) power from the power source according to the setpoint input; and step up a voltage of the DC power to generate an output voltage; at least one lossy inductor connected to an input terminal of the step-up converter, wherein the at least one lossy inductor is configured to convert an input current of the DC power being drawn into a first amount of heat; and a pulse load connected to an output terminal of the step-up converter, wherein the pulse load is configured to convert a current of the output voltage into a second amount of heat; and the at least one monitor device being configured to verify power delivery of the power source based on the DC power being drawn.
Example 9: The system of Example 8, wherein the at least one lossy inductor includes a first lossy inductor and a second lossy inductor.
Example 10: The system of any one of Examples 8 and 9, wherein: the first lossy inductor is connected between the power source and an input capacitor; and the second lossy inductor is connected between the input capacitor and an input terminal of the step-up converter.
Example 11: The system of any one of Examples 8 to 10, wherein the pulse load is a non-inductive load resistor.
Example 12: The system of any one of Examples 8 to 11, further comprising a turn-off snubber connected between the at least one lossy inductor and an output terminal of the step-up converter.
Example 13: The system of any one of Examples 8 to 12, wherein the step-up converter, the at least one lossy inductor and the pulse load are constructed on a printed circuit board (PCB).
Example 14: The system of any one of Examples 8 to 13, wherein the PCB is a metal-core PCB interfaced with at least one cooling component.
Example 15: The system of any one of Examples 8 to 14, wherein the at least one monitor device is configured to verify the at least one cooling component based on a temperature of the electrical load.
Example 16: A structure comprising: a printed circuit board (PCB); a step-up converter constructed on the PCB, wherein the step-up converter is configured to: receive a setpoint input that indicates a desired amount of power to draw from a power source; draw direct current (DC) power from the power source according to the setpoint input; and step up a voltage of the DC power to generate an output voltage; at least one lossy inductor constructed on the PCB, wherein the at least one lossy inductor is connected to an input terminal of the step-up converter, and the at least one lossy inductor is configured to convert an input current of the DC power being drawn into a first amount of heat; and a pulse load constructed on the PCB, wherein the pulse load is connected to an output terminal of the step-up converter, and the pulse load is configured to convert a current of the output voltage into a second amount of heat.
Example 17: The structure of Example 16, wherein the at least one lossy inductor includes a first lossy inductor and a second lossy inductor.
Example 18: The structure of any one of Examples 16 and 17, wherein: the first lossy inductor is printed on the PCB and positioned between the power source and an input capacitor; and the second lossy inductor is printed on the PCB and positioned between the input capacitor and an input terminal of the step-up converter.
Example 19: The structure of any one of Examples 16 to 18, wherein the pulse load is a non-inductive load resistor printed on the PCB.
Example 20: The structure of any one of Examples 16 to 19, wherein the PCB is a metal-core PCB interfaced with at least one cooling component.

### Terminology

Server, as used herein, may refer to any computer or computing device that receives and/or provides information to clients on a computer network (e.g., wired, fiberoptic, wireless, or some combination thereof). The server may be an application server, a catalog server, a communications server, a computing server, a database server, a storage server, a machine learning server, a predictive analysis server, a fax server, a file server, a game server, a mail server, a media server, a print server, a sound server, a proxy server, a virtual server, a web server, some combination thereof, or a sever serving a different purpose or having a different type of architecture.

The server may include at least one processing unit configured to execute various operations of the server. The processing unit may include one or more processors, one or more central processing units (CPUs), one or more graphics processing units (GPUs), one or more application-specific integrated circuits (ASICs), one or more controllers or microcontrollers, one or more ladder logic controllers, one or more other types of control logic, conventional control systems (e.g., relays, switches, delays) or some combination thereof.

To cool the server, the server may include a cooling system. For example, the server may include a liquid cooling system configured to draw heat from the processing unit. The heat gathered from the processing unit can then be drawn away from the server (e.g., to an outside of a room or building). The cooling system may also, alternatively or additionally, include one or more fans configured to cool components of the server and/or work in conjunction with, or instead of, the liquid cooling system.

When implemented as a liquid cooling system, the cooling system may include one or more drip trays configured to capture leaking coolant from inside the server. The drip trays may be cascading (e.g., an effluent from one becomes an influent for another) and may contain one or more sensors configured to detect whether liquid is within the drip trays.

The liquid cooling system may also contain one or more fluid connections. The fluid connections may include quick-disconnect fittings attached to an external surface of the server. The quick disconnect fittings may be coupled to a heat exchanger within the server (e.g., proximate the processing unit). The fluid connections may be configured to attach to a cooling system or a manifold attached to other servers (e.g., within a same rack, within an adjacent rack, or in some other configuration).

The server may be a standard width (e.g., 19 inches or 21 inches) or a custom dimension. The server may also have any suitable depth. For example, the server may be arranged to not exceed approximately one meter in depth.

The server may contain computer-readable storage memory or media (CRM). The CRM may contain random access memory (RAM), electrically erasable programmable read-only memory (EEPROM), flash memory, one or more disk drives, or some combination thereof. The CRM may contain instructions that cause the processing unit to perform various functions of the server. The CRM may be software, firmware, or some combination thereof. The CRM may also include and/or hold data for the server to use for various functionalities.

The server may also include a power supply configured to supply power to various components within the server. The power supply may be configured to adapt or change incoming power (e.g., alternating current to direct current and/or stepping up or stepping down voltage). Furthermore, the power supply may be configured to supply different power to different components of the server.

The server may include one or more sensors configured to facilitate various functionalities of the server. For example, the sensors may include temperature, humidity, sound, tamper, vibration/shock, and/or moisture sensors. The sensors may also be disposed on an exterior of the server (e.g., on a rack or in a facility proximate the server).

The server may also include one or more clocks. The clocks may enable various functionalities of the server to be timed and/or synchronized with another server or computing device.

The server may also include or otherwise be functional to implement one or more alarms. The alarms may be based on any of the sensors above and/or any other logic or instructions executing within the server. For example, the server may be able to notify a surrounding environment (e.g., via an audible tone) or another server or computing device (e.g., a server monitoring system) that a leak has occurred or that the server is overheating.

The server may be a stand-alone unit or may be attached to a server rack. The server rack (or simply, rack), may hold any number of servers. Outside of the rack, the server may include a Level 10 assembly. When installed in the rack with one or more other servers, the server may become part of a Level 11 assembly (e.g., rack-level or multi-rack level).

The server may be installed and/or removed from the rack via any means. For example, guide rails may be used to slide the server into and out of the server rack while latches and/or fasteners may be used to secure the server to the server rack.

The rack may contain a centralized heat transfer system configured to draw heat from the servers disposed therein. The heat transfer system may include one or more manifolds directing/gathering liquid coolant to/from the servers. The heat transfer system may also include a side car unit or attach to a facility heat transfer system.

As part of the heat transfer system, the rack may contain one or more drip trays and/or associated systems. For example, the drip trays may contain a set of cascading drip trays and may have one or more alarms based on liquid being within one or more of the trays.

### Conclusion

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A device comprising:
a step-up converter configured to:
receive a setpoint input that indicates a desired amount of power to draw from a power source;
draw direct current (DC) power from the power source according to the setpoint input; and
step up a voltage of the DC power to generate an output voltage;
at least one lossy inductor connected to an input terminal of the step-up converter, wherein the at least one lossy inductor is configured to convert an input current of the DC power being drawn into a first amount of heat; and
a pulse load connected to an output terminal of the step-up converter, wherein the pulse load is configured to convert a current of the output voltage into a second amount of heat.

2. The device of claim 1, wherein the at least one lossy inductor includes a first lossy inductor and a second lossy inductor.

3. The device of claim 2, wherein:
the first lossy inductor is connected between the power source and an input capacitor; and
the second lossy inductor is connected between the input capacitor and an input terminal of the step-up converter.

4. The device of claim 1, wherein the pulse load is a non-inductive load resistor.

5. The device of claim 1, further comprising a turn-off snubber connected between the at least one lossy inductor and an output terminal of the step-up converter.

6. The device of claim 1, wherein the step-up converter, the at least one lossy inductor and the pulse load are constructed on a printed circuit board (PCB).

7. The device of claim 6, wherein the PCB is a metal-core PCB interfaced with at least one cooling component.

8. A system comprising:
at least one monitor device; and
an electrical load comprising:
a step-up converter configured to:
receive a setpoint input that indicates a desired amount of power to draw from a power source;
draw direct current (DC) power from the power source according to the setpoint input; and
step up a voltage of the DC power to generate an output voltage;
at least one lossy inductor connected to an input terminal of the step-up converter, wherein the at least one lossy inductor is configured to convert an input current of the DC power being drawn into a first amount of heat; and
a pulse load connected to an output terminal of the step-up converter, wherein the pulse load is configured to convert a current of the output voltage into a second amount of heat,
wherein the at least one monitor device is configured to verify power delivery of the power source based on the DC power being drawn.

9. The system of claim 8, wherein the at least one lossy inductor includes a first lossy inductor and a second lossy inductor.

10. The system of claim 9, wherein:
the first lossy inductor is connected between the power source and an input capacitor; and
the second lossy inductor is connected between the input capacitor and an input terminal of the step-up converter.

11. The system of claim 8, wherein the pulse load is a non-inductive load resistor.

12. The system of claim 8, further comprising a turn-off snubber connected between the at least one lossy inductor and an output terminal of the step-up converter.

13. The system of claim 8, wherein the step-up converter, the at least one lossy inductor and the pulse load are constructed on a printed circuit board (PCB).

14. The system of claim 13, wherein the PCB is a metal-core PCB interfaced with at least one cooling component.

15. The system of claim 14, wherein the at least one monitor device is configured to verify the at least one cooling component based on a temperature of the electrical load.

16. A structure comprising:
a printed circuit board (PCB);
a step-up converter constructed on the PCB, wherein the step-up converter is configured to:
receive a setpoint input that indicates a desired amount of power to draw from a power source;
draw direct current (DC) power from the power source according to the setpoint input; and
step up a voltage of the DC power to generate an output voltage;
at least one lossy inductor constructed on the PCB, wherein the at least one lossy inductor is connected to an input terminal of the step-up converter, and the at least one lossy inductor is configured to convert an input current of the DC power being drawn into a first amount of heat; and
a pulse load constructed on the PCB, wherein the pulse load is connected to an output terminal of the step-up converter, and the pulse load is configured to convert a current of the output voltage into a second amount of heat.

17. The structure of claim 16, wherein the at least one lossy inductor includes a first lossy inductor and a second lossy inductor.

18. The structure of claim 17, wherein:
the first lossy inductor is printed on the PCB and positioned between the power source and an input capacitor; and
the second lossy inductor is printed on the PCB and positioned between the input capacitor and an input terminal of the step-up converter.

19. The structure of claim 16, wherein the pulse load is a non-inductive load resistor printed on the PCB.

20. The structure of claim 16, wherein the PCB is a metal-core PCB interfaced with at least one cooling component.
